(19) United States
(12) Patent Application Publication
(10) Pub. No.: US 2026/0130039 A1
(43) Pub. Date: May 7, 2026

(54) LOW-VOLTAGE ORGANIC LIGHT-EMITTING SYNAPSE ELEMENT AND STIMULUS-SENSITIVE NEUROMORPHIC DISPLAY DEVICE COMPRISING SAME

(71) Applicant: SEOUL NATIONAL UNIVERSITY R&DB FOUNDATION, Seoul (KR)

(72) Inventors: Tae Woo LEE, Seoul (KR); Kwan Nyeong KIM, Gyeonggi-do (KR); Huan Yu ZHOU, Seoul (KR)

(21) Appl. No.: 18/867,563

(22) PCT Filed: May 19, 2023
(86) PCT No.: PCT/KR2023/006868

§ 371 Date: Nov. 10, 2025

(30) Foreign Application Priority Data
May 20, 2022 (KR) 10-2022-0061982

(51) Int. Cl. H10K 10/46; H10K 50/30; H10K 85/10

(52) U.S. Cl. CPC H10K 10/471; H10K 10/464; H10K 50/30; H10K 85/114

(57) ABSTRACT

The present disclosure relates to an organic light-emitting layer having improved ion transport properties, an organic light-emitting synaptic device that may be driven at a low voltage, and a stimuli-responsive neuromorphic display device using the synaptic device capable of in-display signal processing that may receive signals from living body and environment and perform immediate visualization together with a bio-like signal processing process.

### TECHNICAL FIELD

The present disclosure relates to an organic light-emitting synaptic device including an organic light-emitting layer having improved ionic conductivity, and a stimuli-responsive neuromorphic display device using the device. The present specification claims priority to and the benefits of Korean Patent Application No. 10-2022-0061982, filed with the Korean Intellectual Property Office on May 20, 2022, the entire contents of which are incorporated herein by reference.

### BACKGROUND ART

With the development of Internet of Things (IoT), metabus, AI and the like, current devices and systems using existing Von Neumann-based computing units are experiencing limitations in energy consumption and data processing speed. To address these challenges, neuromorphic devices and systems have emerged, designed to mimic the structure and operational principles of biological nervous systems for efficient signal processing, and synaptic devices have been developed as a neuromorphic computing unit.

However, in order to realize Internet of Things (IoT), metabus and AI, interactions with users through displays are essential, and existing computing units or display control units are essential in order to process signals with synaptic devices and operate displays, which Causes limitations in energy consumption and data processing speed again. Accordingly, a new type of device is required to solve such limitations in display operation.

A light-emitting synaptic device in which a synaptic device and a light-emitting device are integrated into a single device has both neuroplasticity properties of a synaptic device and light-emitting properties in the single device, thereby having advantages in device integration, energy consumption and data processing speed. A light-emitting transistor using an device structure of an organic light-emitting transistor has been reported recently (Yusheng Chen, Hanlin Wang, Yifan Yao, Ye Wang, Chun Ma, and Paolo Samor_*, Adv. Mater.2021, 33, 2103369), however, it has limitations in high voltage driving of an organic light-emitting transistor and complicated process for manufacturing charge transport layer/light-emitting layer/charge injection layer. Accordingly, in order to solve these limitations, development of a light-emitting synaptic device that enables low voltage driving and is manufacturable using a simple process, and development of a bio-signal processing system using the same have been required.

### PRIOR DOCUMENTS

(Patent Document 1) KR 10-2019-0136419 A

(Patent Document 2) KR 10-2019-0136402 A

### DISCLOSURE

### Technical Problem

The present disclosure is directed to providing an organic light-emitting layer having improved ion transport properties in which an organic light-emitting material and a plasticizer are mixed, a method for manufacturing the organic light-emitting layer, and an organic light-emitting synaptic device employing the same providing luminescence output and current output at the same time under an electrochemical doping-based driving principle, and more specifically, providing an organic light-emitting synaptic device having a transistor structure that may be driven at a low voltage of 2.5 V or less by solving a problem such as high driving voltage of 30 V or greater of an existing organic light-emitting synaptic device having a transistor structure imitating a biological synaptic response.

The present disclosure is also directed to providing a stimuli-responsive neuromorphic display device capable of in-display signal processing that may receive signals from a living body and environment and perform immediate visualization together with a bio-like signal processing process by using a light-emitting-type artificial nervous system formed with an artificial sensory receptor circuit, an artificial neuron circuit and an organic light-emitting synaptic device.

The present disclosure is also directed to providing a stimuli-responsive neuromorphic display device capable of signal processing like biological nerves and synapses and immediate warning at the same time in response to a danger signal by driving a plurality of light-emitting pixels through a simple method using electrolyte gating of an organic light-emitting synaptic device having a transistor structure without an external computer or control circuit for driving the plurality of light-emitting pixels.

However, objects to be addressed by the present disclosure are not limited to the object mentioned above, and other objects not mentioned will be clearly appreciated by those skilled in the art from the following description.

### Technical Solution

One embodiment of the present disclosure provides an organic light-emitting synaptic device including: an organic light-emitting layer including an organic light-emitting material and a plasticizer; an ionic dielectric layer; and two or more terminals, wherein the plasticizer includes a surfactant having both hydrophilicity and hydrophobicity, and the organic light-emitting synaptic device provides luminescence output and current output at the same time under an electrochemical doping-based driving principle.

Another embodiment of the present disclosure provides a stimuli-responsive neuromorphic display device including: at least one artificial sensory receptor circuit that senses stimuli; at least one artificial neuron circuit that receives a voltage signal from the artificial sensory receptor circuit, determines a threshold of the stimuli, and outputs a spike signal when breaking through the threshold; and the organic light-emitting synaptic device according to one embodiment of the present disclosure that accumulates the spike signal and visualizes it through luminescence.

### Advantageous Effects

An organic light-emitting layer according to one embodiment of the present disclosure has improved ionic conductivity, and therefore, can be useful for increasing luminescence intensity and reducing driving voltage of various electrochemical driving-based light-emitting devices, such as electrochemical organic light-emitting cells and transistors or electrochemical organic/inorganic light-emitting devices.

An organic light-emitting synaptic device according to one embodiment of the present disclosure can be driven at a low voltage.

Signal processing using a stimuli-responsive neuromorphic display device according to one embodiment of the present disclosure is capable of reducing a size of the device and reducing the driving voltage by controlling electrochemical doping of an organic light-emitting layer through electrolyte gating without large and hard external computing and control units, and therefore, the device can be applied to various electronic systems such as wearable display fields, AR/VR fields or robotics fields to improve efficiency of visualization processes.

The stimuli-responsive neuromorphic display device according to one embodiment of the present disclosure provides a warning signal through luminescence. Therefore, it is possible to provide bio-like responses and immediate and intuitive warning signals to dangerous stimuli for patients suffering from sensory disorders such as peripheral neuropathy, somatosensory disorder, sensory neuropathy, mental sensory disorder, cerebral palsy and autogenic sensory neuropathy who wear the device.

Effects of the present disclosure are not limited to the above-described effects, and effects not mentioned will be clearly appreciated by those skilled in the art from the present specification and accompanying drawings.

### BRIEF DESCRIPTION OF DRAWINGS

FIG. 1 is a schematic diagram illustrating an organic light-emitting synaptic device having a transistor structure including three or more terminals according to one embodiment of the present disclosure, and component materials thereof.

FIG. 2 is a schematic diagram illustrating a stimuli-responsive neuromorphic display device according to one embodiment of the present disclosure.

FIG. 3a is a graph presenting luminescence intensity-gate voltage (optical transport) properties of the organic light-emitting synaptic device.

FIG. 3b is a graph presenting turn-on gate voltage properties of the organic light-emitting synaptic device depending on the weight ratio of Triton X-100 with respect to MEH-PPV.

FIG. 3c is a graph presenting luminescence intensity-drain voltage (optical output) properties of the organic light-emitting synaptic device.

FIG. 4a is a graph presenting drain current-gate voltage (electric transport) properties of the organic light-emitting synaptic device.

FIG. 4b is a graph presenting gate current-gate voltage (electric leakage) properties of the organic light-emitting synaptic device.

FIG. 4c is a graph presenting drain current-drain voltage (electric output) properties of the organic light-emitting synaptic device.

FIG. 5 shows atomic force microscope images presenting changes in the surface morphology of the organic light-emitting layer depending on the weight ratio of Triton X-100 with respect to MEH-PPV.

FIG. 6a is a Nyquist plot of the organic light-emitting layer depending on the weight ratio of Triton X-100 with respect to MEH-PPV measured using an electrochemical impedance spectrometer.

FIG. 6b is a graph presenting ionic conductivity depending on the weight ratio of Triton X-100 with respect to MEH-PPV.

FIG. 7 is a graph presenting spectra of photoluminescence and electroluminescence of the organic light-emitting synaptic device.

FIG. 8 shows graphs presenting changes in the voltage-dependent absorbance of the organic light-emitting layer depending on the weight ratio of Triton X-100 with respect to MEH-PPV measured using a UV-visible spectrophotometer.

FIG. 9a is a graph presenting excitatory postsynaptic current (EPSC) properties depending on an input spike voltage of the organic light-emitting synaptic device.

FIG. 9b is a graph presenting spike number dependent plasticity of the organic light-emitting synaptic device.

FIG. 9c is a graph presenting spike frequency dependent plasticity of the organic light-emitting synaptic device.

FIG. 9d is a graph presenting spike duration dependent plasticity of the organic light-emitting synaptic device.

FIG. 10a is a mimetic diagram of a stimuli-responsive neuromorphic display device using in-display signal processing.

FIG. 10b is a photograph of an organic artificial synaptic device emitting light in a stimuli-responsive neuromorphic display device manufactured in Example 2.

FIG. 10c is a graph presenting an output sensor voltage of a voltage divider depending on temperature.

FIG. 10d shows graphs presenting output frequency and spike of an artificial neuron circuit depending on temperature.

FIG. 10e shows photographs presenting changes in the light-emitting area of the stimuli-responsive neuromorphic display device at 58° C. and a graph presenting an output current.

### MODE FOR INVENTION

Throughout the specification, a description of a certain part “including” certain constituents means that it may further include other constituents, and does not exclude other constituents unless particularly stated on the contrary.

Throughout the specification, a description of a certain member being placed “on” another member includes not only a case of the certain member being in contact with the another member but a case of still another member being present between the two members.

Throughout the specification, “A and/or B” means “A and B, or A or B”.

Hereinafter, the present disclosure will be described in more detail.

One embodiment of the present disclosure provides an organic light-emitting synaptic device including: an organic light-emitting layer including an organic light-emitting material and a plasticizer; an ionic dielectric layer; and two or more terminals, wherein the plasticizer includes a surfactant having both hydrophilicity and hydrophobicity, and the organic light-emitting synaptic device provides luminescence output and current output at the same time under an electrochemical doping-based driving principle.

The organic light-emitting synaptic device according to one embodiment of the present disclosure may be driven at a voltage of 2.5 V or less.

### Organic Light-Emitting Layer

According to one embodiment of the present disclosure, the organic light-emitting layer has improved ion transport properties by including an organic light-emitting material and a plasticizer that includes a surfactant having both hydrophilicity and hydrophobicity. Accordingly, when an electrochemical organic/inorganic light-emitting device includes the organic light-emitting layer, the light-emitting device may have increased luminescence intensity and decreased driving voltage.

According to one embodiment of the present disclosure, the organic light-emitting material may be an organic small-molecule light-emitting material having a conjugation structure, an organic polymer light-emitting material having a conjugation structure, an organic/inorganic perovskite light-emitting material, or a mixture thereof.

Specifically, the organic small-molecule light-emitting material may include one selected from the group consisting of pentacene, TIPS-pentacene (6, 13-bis(triisopropylsilylethynyl) pentacene), rubrene, tetracene, anthracene, triethylsilylethynyl anthradithiophene (TES ADT), (6,6)-phenyl-C61 butyric acid methyl ester (PCBM), fluorene, pyrene, tris(2-phenylpyridine)iridium(III) (Ir(ppy)₃), (2-phenylpyridine) (acetylacetonate)iridium(III) (Ir(ppy)₂(acac)), 4,4′-bis(N-carbazolyl)-1,1′-biphenyl (CBP), spiro-OMeTAD (2,2′, 7,7′-tetrakis (N,N-di-p-methoxyphenylamine) 9,9′-spirobifluorene), 2,2′-bipyridine (bpy), 1,10-phenanthroline (phen), perylene, poly (p-phenylene vinylene) (PPV) and combinations thereof.

The organic polymer light-emitting material may include one selected from the group consisting of polythiophene, poly(3-hexylthiophene) (P3HT), poly(3-octylthiophene) (P30T), poly(butylthiophene) (PBT), poly(3,4-ethylenedioxythiophene) (PEDOT), poly(9-vinylcarbazole) (PVK), poly(p-phenylene vinylene), poly(thienylene vinylene) (PTV), polyacetylene, polyfluorene, polyaniline, polypyrrole, diketopyrrolopyrrole-based copolymers, isoindigo-based copolymers, derivatives thereof and combinations thereof.

The organic/inorganic perovskite light-emitting material may include one selected from the group consisting of formamidinium lead trihalide (FAPbX₃, X═Cl, Br, I), methylammonium lead trihalide (MAPbX₃, X═Cl, Br, I), phenethylammonium lead trihalide (PEAPbI₃), guanidinium lead thiocyanate (GAPb(SCN)₃), cesium lead bromide (CsPbBr₃), cesium lead iodide (CsPbI₃), cesium lead chloride/bromide (CsPb(Cl/Br)₃), cesium lead chloride/iodide (CsPb(Cl/I)₃) and combinations thereof.

According to one embodiment of the present disclosure, the surfactant may be a nonionic surfactant, an ionic surfactant or a mixture thereof.

Specifically, the nonionic surfactant may include one selected from the group consisting of polysorbate, polyethylene glycol (PEG), nonoxynol-9, octoxynol-9 (Triton X-100), alkyl polyglucoside (APG), ethylene oxide/propylene oxide copolymers, derivatives thereof and combinations thereof.

The ionic surfactant may include one selected from the group consisting of sodium dodecyl sulfate (SDS), sodium lauryl sulfate (SLS), cetyltrimethylammonium bromide (CTAB), benzalkonium chloride (BAC), cocamidopropyl betaine (CAPB), sodium cocoyl isethionate (SCI), dioctyl sulfosuccinate (DOSS), sodium oleate, sodium stearate, sodium cholate, derivatives thereof and combinations thereof.

According to one embodiment of the present disclosure, the plasticizer included in the organic light-emitting layer may be included in an amount of 10 parts by weight or greater and 50 parts by weight or less with respect to 100 parts by weight of the organic light-emitting material. More specifically, the plasticizer included in the organic light-emitting layer may be included in an amount of 10 parts by weight or greater and 40 parts by weight or less, 10 parts by weight or greater and 35 parts by weight or less, 10 parts by weight or greater and 30 parts by weight or less, 20 parts by weight or greater and 40 parts by weight or less, 20 parts by weight or greater and 35 parts by weight or less, or 25 parts by weight or greater and 35 parts by weight or less with respect to 100 parts by weight of the organic light-emitting material, and may be preferably included in an amount of 25 parts by weight or greater and 35 parts by weight or less with respect to 100 parts by weight of the organic light-emitting material.

By including the plasticizer in the above-described range, ion transport properties of the organic light-emitting layer may be improved, a threshold voltage of luminescence is reduced in the organic light-emitting synaptic device including the organic light-emitting layer, enabling driving of the device even at a low voltage, and an on current that is a current flowing when the organic light-emitting synaptic device including the organic light-emitting layer is in a driving state is reduced, thereby reducing power consumption of the device.

### Organic Light-emitting Synaptic Device

The organic light-emitting synaptic device according to one embodiment of the present disclosure is a single device, and may have at least one structure selected from the group consisting of a transistor, a diode, a resistor, a capacitor, an inductor, an ion pump, an ion cell (battery), a flash memory, a magnetic random access memory, a memristor, a resistive random access memory, a magnetoresistive random access memory and a phase-change memory. More specifically, the organic light-emitting synaptic device may have a transistor structure including two or more terminals, or a transistor structure including three or more terminals.

The organic light-emitting synaptic device according to one embodiment of the present disclosure may simultaneously perform a role of a synaptic device that processes an applied electric signal and a role of a light-emitting device that visualizes the processed signal through luminescence in a single device, thereby improving integration of an electronic system using the same.

The organic light-emitting synaptic device according to one embodiment of the present disclosure has an electrochemical driving-based operation principle, and may be operated through increasing charge conductivity of the light-emitting layer by ion doping and luminescence intensity of the synaptic device. Specifically, the organic light-emitting synaptic device may control electrochemical doping of the organic light-emitting layer using electrolyte gating.

According to one embodiment of the present disclosure, the ionic dielectric layer may form polarization by an applied electric signal.

According to one embodiment of the present disclosure, the ionic dielectric layer may include an ionic dopant characterized in that cations and anions are separated by an applied electric signal.

According to one embodiment of the present disclosure, the ionic dopant includes materials such as ion-containing metals, ceramics, polymers, semiconductors and dielectrics, but is not particularly limited thereto.

Specifically, the ionic dopant may include cations of imidazolium, ammonium, pyrrolidinium, sulphonium, phosphonium, pyridinium and derivatives thereof; anions of chloride, iodide, bromide, sulfate, sulfonate, phosphate, phosphinate, aluminate, acetate, thiocyanate, dicyanamide, borate, antimonite, bis(sulfonyl) imide-based, tosylate, nitrate, decanoate, thiosalicylate, benzoate and derivatives thereof; or mixtures thereof.

For example, the ionic dopant may include one selected from among cations of 1-ethyl-3-methylimidazolium, 1-butyl-3-methylimidazolium, methyl-tributylammonium, 1,2,3-trimethylimidazolium, methylimidazolium, 1-ethyl-2,3-dimethylimidazolium, 1-butyl-2,3-dimethylimidazolium, 1-dodecyl-3-methylimidazolium, 1-butyl-1-methylpyrrolidinium, N-methyl-N-trioctylammonium, N-butyl-N-methylpyrrolidinium, triethylsulphonium, tetraethylammonium, tetrabutylphosphonium, methyltrioctylammonium, 3-methyl-1-propylpyridinium, 1,2-dimethyl-3-propylimidazolium, 1-hexyl-3-methylimidazolium, 1-methyl-3-octylimidazolium, 1-butyl-4-methylpyridinium, 1,3-dimethylimidazolium, 4-(3-butyl-1-imidazolio)-1-butanesulfonic acid, 3-(triphenylphosphonio)propane-1-sulfonic acid, 1-allyl-3-methylimidazolium, 1-butyl-1-(3,3,4,4,5,5,6,6,7,7,8,8,8-tridecafluorooctyl)-imidazolium, 1-methyl-3-(3,3,4,4,5,5,6,6,7,7,8,8,8-tridecafluoro-octyl)-imidazolium; anions of chloride, methanesulfonate, methylsulfate, hydrogensulfate, tetrachloroaluminate, acetate, methyl sulfate, thiocyanate, ethyl sulfate, tetrafluoroborate, dicyanamide, hexafluoroantimonate, hexafluorophosphate, bis(trifluoromethyl sulfonyl)imide, trifluoromethane sulfonate, iodide, nitrate, bromide, bis(pentafluoroethylsulfonyl)-imide, tosylate, octyl sulfate, bis(2,4,4-trimethyl-pentyl)phosphinate, decanoate, thiosalicylate, triflate-2-(2-methoxyethoxy)-ethyl sulfate, nonafluorobutanesulfonate, benzoate, heptadecafluorooctanesulfonate; and mixtures thereof.

According to one embodiment of the present disclosure, the organic light-emitting synaptic device may include a substrate. Specifically, the substrate may include at least one material selected from among at least one conductor material selected from the group consisting of chromium, aluminum, iron, stainless steel and combinations thereof; at least one semiconductor material selected from the group consisting of germanium, silicon, gallium arsenide and combinations thereof; at least one insulator material selected from the group consisting of glass, sapphire, paper, plastic films and combinations thereof; and at least one flexible-stretchable substrate material selected from the group consisting of polyimide, polyethylene terephthalate, polyethylene naphthalate, polycarbonate, polyacrylate, polyethersulfone, polypropylene, polydimethylsiloxane, polymethylphenylsiloxane, polydiphenylsiloxane, polysiloxane, polyurethane, polystyrene, styrene-butadiene copolymers, polystyrene copolymers, EcoFlex and combinations thereof.

The organic light-emitting synaptic device having a transistor structure including three or more terminals according to one embodiment of the present disclosure may include a gate electrode; the organic light-emitting layer forming a channel region; the ionic dielectric layer including an ionic dopant formed between the gate electrode and the channel region; a source electrode connected to the channel region; and a drain electrode connected to the channel region.

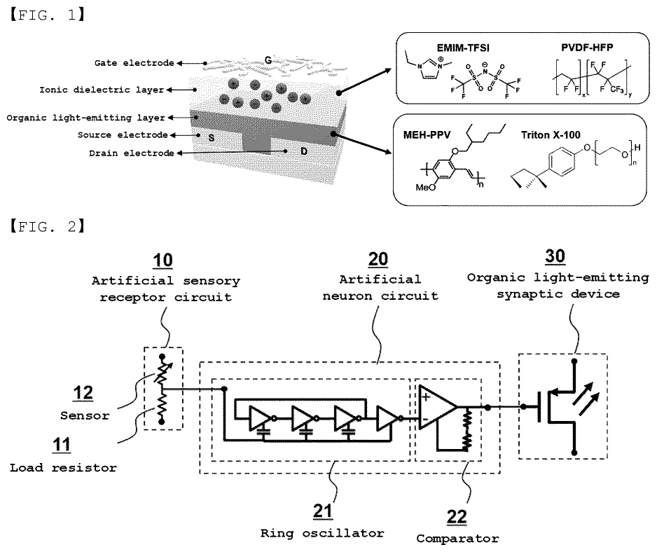

FIG. 1 is a schematic diagram illustrating an organic light-emitting synaptic device having a transistor structure including three or more terminals according to one embodiment of the present disclosure, and component materials thereof.

According to one embodiment of the present disclosure, the gate electrode may control electrochemical doping from the ionic dielectric layer to the channel region. Specifically, the gate electrode may control electrochemical doping of the organic light-emitting layer. The material of the gate electrode may include at least one selected from the group consisting of organic materials, nano materials, metal nano materials and liquid metal materials, but is not particularly limited thereto.

The organic light-emitting synaptic device having a transistor structure according to one embodiment of the present disclosure overcomes the limitation of high driving voltage of an organic light-emitting transistor-based light-emitting synaptic device having an existing field effect driving principle operating at 30 V to 120 V through applying an electrochemical doping-based driving principle, enabling low-voltage driving. Therefore, the organic light-emitting synaptic device according to one embodiment of the present disclosure may be applied to wearable devices due to low energy consumption and miniaturization, and. The low voltage required to manufacture a wearable device by combining with an analog circuit element such as an existing commercialized transistor driven at a low voltage may be −5 V or greater and 5 V or less, for example, −5 V, −4.5 V, −4 V, −3.5 V, −3 V, −2.5 V, 2 V, −1.5 V, −1 V, −0.5 V, 0 V, 0.5 V, 1 V, 1.5 V, 2 V, 2.5 V, 3 V, 3.5 V, 4 V, 4.5 V or 5 V. Preferably, the low voltage may be 2.5 V, −2 V, −1.5 V, −1 V, −0.5 V, 0 V, 0.5 V, 1 V, 1.5 V, 2 V or 2.5 V.

Another embodiment of the present disclosure provides a stimuli-responsive neuromorphic display device including: at least one artificial sensory receptor circuit that senses stimuli; at least one artificial neuron circuit that receives a voltage signal from the artificial sensory receptor circuit, determines a threshold of the stimuli, and outputs a spike signal when breaking through the threshold; and the organic light-emitting synaptic device according to one embodiment of the present disclosure, which accumulates the spike signal and visualizes it through luminescence.

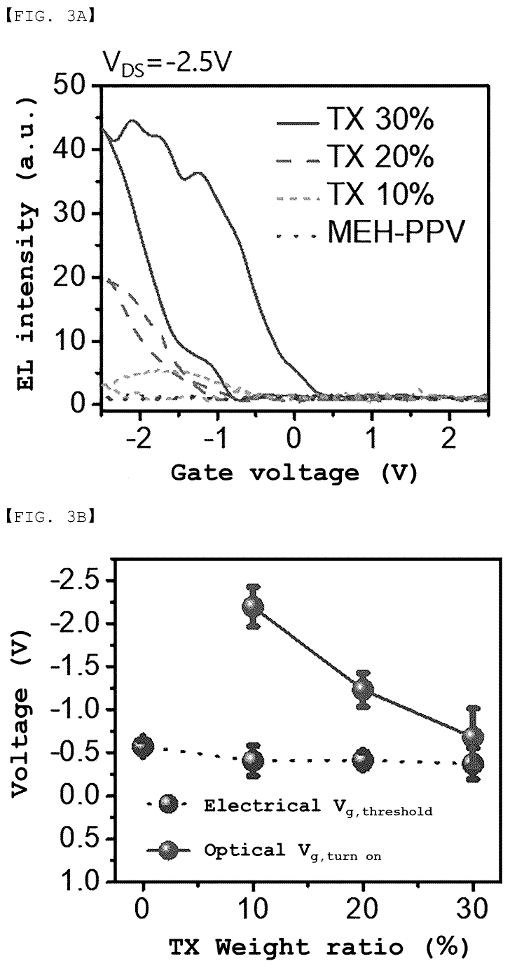

FIG. 2 is a schematic diagram illustrating the stimuli-responsive neuromorphic display device according to one embodiment of the present disclosure.

Referring to FIG. 2, the stimuli-responsive neuromorphic display device will be described.

The stimuli-responsive neuromorphic display device according to one embodiment of the present disclosure may simultaneously perform signal processing similar to biological nerves and visualization through luminescence in response to bio-and environmental signals. The stimuli-responsive neuromorphic display device may include at least one artificial sensory receptor circuit 10 that imitates a sensory receptor of a living body, which senses stimuli and transmits the intensity of the stimuli in the form of a voltage; at least one artificial neuron circuit 20 that receives a voltage signal from the artificial sensory receptor circuit, determines a threshold of the stimuli, and outputs a spike signal when breaking through the threshold; and the organic light-emitting synaptic device 30 that accumulates the spike signal and visualizes it through luminescence.

The basic function of a neuron is to transmit information to another cell through a synapse by generating an electrical spike when receiving stimuli exceeding a threshold. The electric signal generated in this way is referred to as action potential (AP). The synapse not only transmits excitement, but also causes weighting or inhibition depending on temporal/spatial changes in the excitement arriving there to enable high-order integrated action of a nervous system.

In the stimuli-responsive neuromorphic display device according to one embodiment of the present disclosure, the artificial sensory receptor circuit 10 transmits an output voltage to the artificial neuron circuit 20 as external stimuli are applied. A load resistor 11 controls the output voltage according to the ratio between a sensor 12 and the resistor. A ring oscillator 21 generates spikes of frequency and voltage proportional to the sensor voltage by imitating i a bio-spike, and a comparator 22 determines a threshold and transmits the spike signal to the next organic light-emitting synaptic device 30 when breaking through the threshold. As the frequency of the action potential (AP) increases, the light-emitting area and the excitatory postsynaptic current (EPSC) of the drain electrode increase. Such a response mimics biological synaptic potentiation.

The stimuli-responsive neuromorphic display device according to one embodiment of the present disclosure may process signals such as bio-signals and provide immediate warning at the same time in response to a danger signal by driving a plurality of light-emitting pixels through a simple method using electrolyte gating of the organic light-emitting synaptic device having a transistor structure without an external computer or control circuit for driving the plurality of light-emitting pixels. In addition, the stimuli-responsive neuromorphic display device is capable of reducing a size of the device and reducing the driving voltage by controlling electrochemical doping of the organic light-emitting layer through electrolyte gating without large and hard external computing and control units, and therefore, the device can be applied to various electronic systems such as wearable display fields, AR/VR fields or robotics fields to improve efficiency of visualization processes.

According to one embodiment of the present disclosure, the artificial sensory receptor circuit may include at least one load resistor and at least one voltage source.

According to one embodiment of the present disclosure, the artificial sensory receptor circuit may include at least one sensor selected from the group consisting of a temperature sensor, a strain sensor or a pressure sensor, an optical sensor, an image sensor that senses visual information, an acceleration sensor that senses a balance, a gyroscope sensor and a gas sensor that senses chemical substances inside or outside a living body. The temperature sensor may include at least one temperature-sensitive resistive material selected from the group consisting of polymers; carbon nanotubes; carbon nanofibers; carbon black; graphene; graphene oxide; transition metal dichalcogenides; MXene; inorganic semiconductor membranes; metals having a nanostructure of one of nanoparticles, nanorods, nanowires and nanoflakes; and semiconducting nanowires. The temperature sensor may be at least one selected from the group consisting of a piezoresistive strain sensor, a piezoelectric strain sensor, a triboelectric strain sensor and a capacitive strain sensor, which change an electric signal by changing resistance, current, voltage and permittivity according to thermal stimuli or change optical properties by changing light transmittance and light absorptivity.

According to one embodiment of the present disclosure, the artificial neuron circuit may include a ring oscillator that changes the voltage signal into a spike form, and a comparator that determines whether the voltage signal breaks through a threshold.

According to one embodiment of the present disclosure, the threshold may be intensity of stimuli to which a sensory receptor or a pain receptor of a living body responds.

When the stimuli sensed by the artificial sensory receptor circuit are thermal stimuli, the stimuli-responsive neuromorphic display device according to one embodiment of the present disclosure may perform at least one of a low-temperature burn prevention warning function of determining a thermal pain threshold of human skin, and accumulating and visualizing the thermal stimuli; and an overheat warning function of sensing a temperature of an electronic device, and accumulating and visualizing the thermal stimuli.

When the stimuli sensed by the artificial sensory receptor circuit are physical stimuli, the stimuli-responsive neuromorphic display device according to one embodiment of the present disclosure may perform at least one of a function of determining a threshold of pressure causing bedsores and the like on human skin, and accumulating and visualizing the pressure stimuli; a function of measuring noise at an industrial site and visualizing the noise concentration; an arrhythmia warning function of determining and visualizing a heart rate threshold dangerous to a living body; a function of determining a threshold of the degree of bending that strains a joint, and accumulating and visualizing the bending stimuli; a function of determining a threshold of crack formation on a building or a structure such as a bridge caused by physical stimuli such as an earthquake, and accumulating and visualizing the physical stimuli; and a function of measuring an impact applied to a safety helmet, and accumulating and visualizing the impact.

When the stimuli sensed by the artificial sensory receptor circuit are chemical stimuli, the stimuli-responsive neuromorphic display device according to one embodiment of the present disclosure may perform at least one of a function of determining a gas concentration threshold affecting human tissue during breathing and visualizing the gas concentration; a function of measuring and visualizing a carbon dioxide concentration inside a building; a fine dust warning function of measuring and visualizing a fine dust concentration in the air; a function of measuring air quality and visualizing changes in the air quality; and a disease risk warning function of determining and visualizing a threshold of a concentration of a specific molecule indicating a disease in a living body.

When the stimuli sensed by the artificial sensory receptor circuit are electromagnetic stimuli, the stimuli-responsive neuromorphic display device according to one embodiment of the present disclosure may perform at least one of a function of determining a threshold of ultraviolet (wavelength 100 nm to 400 nm) stimuli affecting human tissue, and accumulating and visualizing the ultraviolet stimuli; a function of determining a threshold of X-ray (0.01 nm to 10 nm) stimuli affecting human tissue, and accumulating and visualizing the X-ray stimuli; and a function of determining a threshold of radiation exposure (gamma ray 0.01 nm or less), and visualizing the risk of radiation exposure.

Hereinafter, the present disclosure will be described in detail with reference to examples in order to specifically describe the present disclosure. However, examples according to the present disclosure may be modified to various different forms, and the scope of the present disclosure is not construed as being limited to the examples described below. Examples of the present specification are provided in order to more fully describe the present disclosure to those having average knowledge in the art.

### Preparation Example 1

### Manufacture of Organic Light-Emitting Layer

MEH-PPV (poly[2-methoxy-5-(2-ethylhexyloxy)-1,4-phenylenevinylene], Sigma-Aldrich, average Mn: 40,000 to 70,000) was prepared as an organic light-emitting body material, and Triton X-100 (t-octylphenoxypolyethoxyethanol, polyethylene glycol tert-octylphenyl ether, Sigma-Aldrich) was prepared as a plasticizer material.

Then, Triton X-100 was dissolved in cyclohexanone (Sigma-Aldrich) at a concentration of 10 mg/ml to prepare a Triton X solution first. The concentration of MEH-PPV with respect to cyclohexanone was fixed at 10 mg/ml. MEH-PPV (10 mg) and the Triton X solution were mixed so that the weight ratio of Triton X with respect to MEH-PPV was 30%, and the mixture was vigorously stirred overnight at 50° C. using a magnetic stirrer to prepare an organic light-emitting solution.

The prepared organic light-emitting solution was spin coated on a glass substrate, and dried for 10 minutes at 90° C. Celsius to manufacture an organic light-emitting film including an organic light-emitting layer.

### Preparation Example 2

An organic light-emitting film was manufactured in the same manner as in Preparation Example 1, except that the organic light-emitting solution was prepared so that the weight ratio of Triton X with respect to MEH-PPV was 20%.

### Preparation Example 3

An organic light-emitting film was manufactured in the same manner as in Preparation Example 1, except that the organic light-emitting solution was prepared so that the weight ratio of Triton X with respect to MEH-PPV was 10%.

### Comparative Preparation Example 1

An organic light-emitting film was manufactured in the same manner as in Preparation Example 1, except that Triton X, a plasticizer, was not used, and the organic light-emitting solution was prepared so that the concentration of MEH-PPV with respect to cyclohexanone was 10 mg/ml.

### Example 1-1

### Manufacture of Organic Light-Emitting Synaptic Device

Before forming an ionic dielectric layer, an ionic insulator solution was prepared as follows. Poly (vinylidene fluoride)-co-hexafluoropropylene (PVDF-HFP, Sigma-Aldrich) , 1-ethyl-3-methylimidazolium bis(trifluoromethylsulfonyl) imide (EMIM-TFSI, Sigma-Aldrich) and acetone (Sigma-Aldrich) were mixed in a weight ratio of 1:4:10, and the mixture was vigorously stirred overnight at 50° C. using a magnetic stirrer to prepare an ionic insulator Solution.

A silver nanowire solution (Novarials) (30 μm) was spin coated on a glass substrate, and dried for 5 minutes at 100° C. to be used as a gate electrode.

The ionic insulator solution prepared above was spin coated on the prepared gate electrode, and dried overnight at room temperature to form an ionic dielectric layer on the gate electrode.

A chromium/gold electrode was deposited on a glass substrate using a thermal vapor deposition apparatus, which was used as a source/drain electrode, and a channel region was defined as an interdigitated electrode having a size of about 1.5 mm×2.0 mm. The organic light-emitting solution in which the weight ratio of Triton X with respect to MEH-PPV was 30% prepared in Preparation Example 1 was spin coated on the source/drain electrode, and dried for 10 minutes at 90° C. to form an organic light-emitting layer on the source/drain electrode.

Then, the film prepared above having the ionic dielectric layer formed on the gate electrode was attached so that the ionic dielectric layer was in contact with the organic light-emitting layer surface, and as a result, an organic light-emitting synaptic device having a top-gate structure in which the gate electrode-ionic dielectric layer-organic light-emitting layer-source/drain electrode are formed in this order from the top on a glass substrate was manufactured.

### Example 1-2

### Organic Light-Emitting Synaptic Device

An organic light-emitting synaptic device was manufactured in the same manner as in Example 1-1, except that the organic light-emitting solution prepared so that the weight ratio of Triton X with respect to MEH-PPV was 20% was used.

### Example 1-3

### Organic Light-Emitting Synaptic Device

An organic light-emitting synaptic device was manufactured in the same manner as in Example 1-1, except that the organic light-emitting solution prepared so that the weight ratio of Triton X with respect to MEH-PPV was 10% was used.

### Comparative Example 1

### Organic Light-Emitting Synaptic Device Including Organic Light-emitting Layer Not Including Plasticizer

An organic light-emitting synaptic device was manufactured in the same manner as in Example 1-1, except that the organic light-emitting solution prepared so that Triton X, a plasticizer, was not used and the concentration of MEH-PPV with respect to cyclohexanone was 10 mg/ml was used.

### Example 2

### Manufacture of Stimuli-Responsive Neuromorphic Display Device

An organic light-emitting synaptic device included in a stimuli-responsive neuromorphic display device was prepared in the same manner as in Example 1 except that the channel region was defined as an interdigitated electrode having a size of about 1.5 cm×1.5 cm.

An artificial sensory receptor circuit was formed by connecting a thermistor (10 K, Adafruit) used as a temperature sensor to a load resistor of 10 KΩ. An output terminal of the artificial sensory receptor circuit was connected to an output terminal of an artificial neuron circuit, and the output terminal of the artificial neuron circuit was connected to a gate electrode of the organic artificial synaptic device having a lateral-gate structure to construct a stimuli-responsive neuromorphic display device.

### Experimental Example 1

### Light-Emitting Transistor Properties of Organic Light-emitting Synaptic Device

For each of the organic light-emitting synaptic devices manufactured in Example 1-1 (TX 30%), Example 1-2 (TX 20%), Example 1-3 (TX 10%) and Comparative Example 1 (MEH-PPV), light-emitting transistor properties of the organic light-emitting synaptic device depending on the weight ratio of Triton X-100 with respect to MEH-PPV were measured using a semiconductor analyzer (Keithley) (B1500A) and an optical power detector (photodiode) (818-SL/DB optical power detector, silicon, 400 nm to 1100 nm, DB15 calibration module).

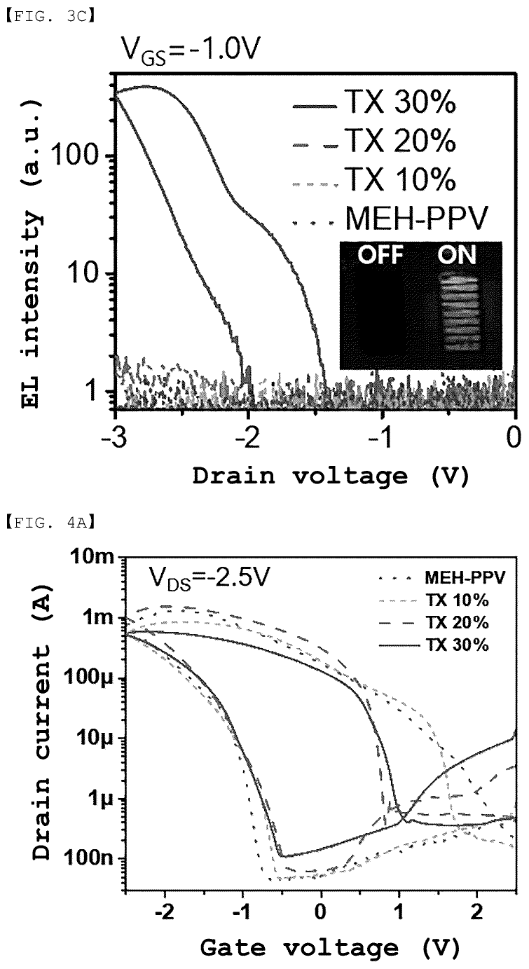

FIG. 3a is a graph presenting luminescence intensity-gate voltage (optical transport) properties of the organic light-emitting synaptic device.

FIG. 3b is a graph presenting turn-on gate voltage properties of the organic light-emitting synaptic device depending on the weight ratio of Triton X-100 with respect to MEH-PPV.

FIG. 3c is a graph presenting luminescence intensity-drain voltage (optical output) properties of the organic light-emitting synaptic device.

Referring to FIGS. 3a and 3b, it was identified that, in the optical transport graph and the turn-on gate voltage property graph presenting output luminescence intensity depending on the gate voltage of the organic light-emitting synaptic device, turn-on gate voltage (Vg, turn-on) of luminescence decreased and maximum luminescence intensity increased as the ratio of Triton X-100 increased.

In addition, referring to FIG. 3c, turn-on drain voltage of luminescence and maximum luminescence intensity increased as the ratio of Triton X-100 increased in the optical output graph presenting output luminescence intensity depending on the drain voltage of the organic light-emitting synaptic device. At the 30% of Triton X-100, luminescence was maintained even when the drain voltage was −2 V or less in the hysteresis measurement. Despite the fact that the organic light-emitting layer has a bandgap of 2.177 eV, maintaining luminescence at a voltage lower than the bandgap is possible by improving ion transport properties resulting from the addition of Triton X-100. Accordingly, by allowing ions to reach the source-drain electrodes, energy band bending is induced in the organic light-emitting layer near the electrodes, facilitating injection of electrons and holes, and this may be a method advantageous for developing low-voltage electrochemical devices.

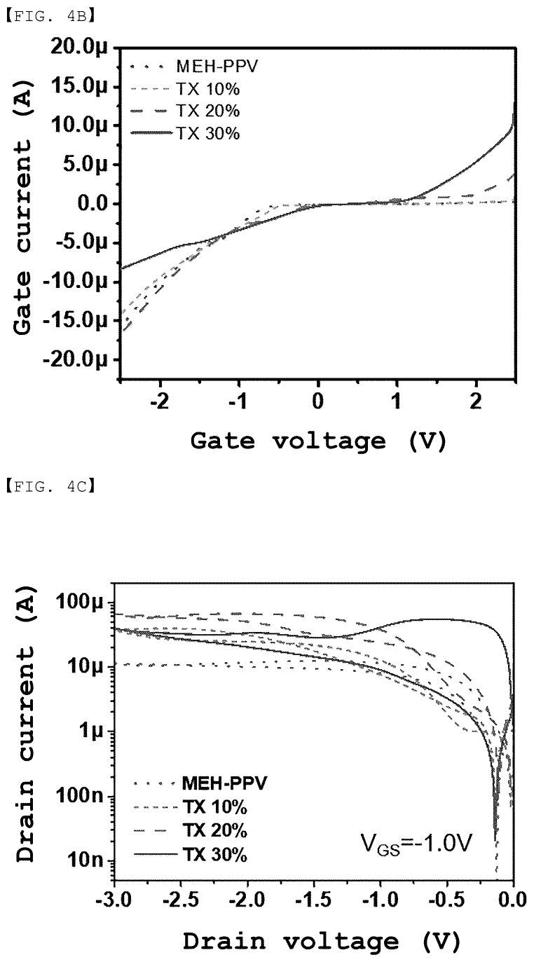

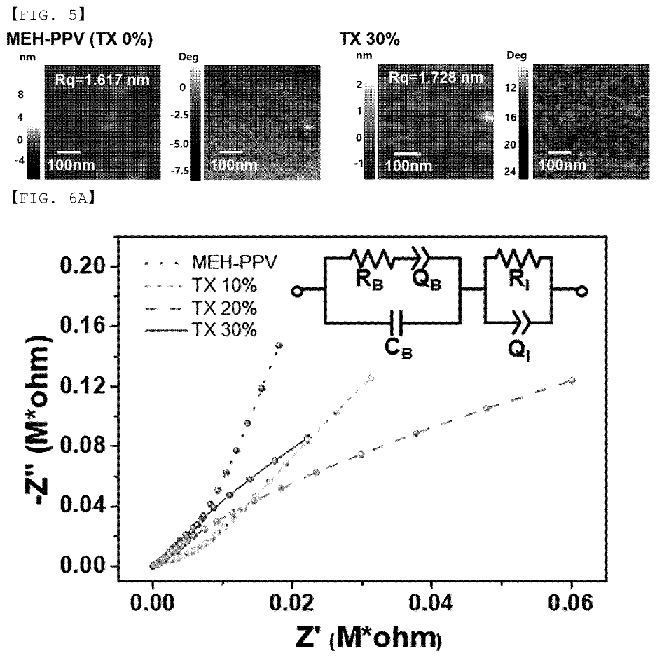

FIG. 4a is a graph presenting drain current-gate voltage (electric transport) properties of the organic light-emitting synaptic device.

FIG. 4b is a graph presenting gate current-gate voltage (electric leakage) properties of the organic light-emitting synaptic device.

FIG. 4c is a graph presenting drain current-drain voltage (electric output) properties of the organic light-emitting synaptic device.

Referring to FIG. 4a, in the transport graph (transfer curve) presenting an output current depending on the gate voltage of the organic light-emitting synaptic device, the threshold voltage of current decreased as the ratio of Triton X-100 increased and the on current decreased when the weight ratio of Triton X-100 with respect to MEH-PPV was 30%. Ion transport properties of the organic light-emitting layer are improved by adding Triton X-100, allowing the transistor to be turned on even at a low voltage, and this may be a method advantageous for developing low-voltage electrochemical devices. In addition, the on current is reduced by adding Triton X-100 having insulating properties, and this may be a method advantageous for developing low-power high performance electrochemical devices.

### Experimental Example 2

### Analysis on Surface Morphology of Organic Light-Emitting Layer

For each of the organic light-emitting layers manufactured in Preparation Example 1 (TX 30%), Preparation Example 2 (TX 20%), Preparation Example 3 (TX 10%) and Comparative Preparation Example 1 (MEH-PPV), changes in the surface morphology of the organic light-emitting layer depending on the weight ratio of Triton X-100 with respect to MEH-PPV were measured using an atomic force microscope.

FIG. 5 shows atomic force microscope images presenting changes in the surface morphology of the organic light-emitting layer depending on the weight ratio of Triton X-100 with respect to MEH-PPV. Specifically, FIG. 5 shows photographs presenting the measurement results of an atomic force microscope.

Referring to FIG. 5, stacking occurs when Triton X-100 is absent due to interactions between the polymer chains of the organic light-emitting material, resulting in a surface morphology of fibril structure. When the weight ratio of Triton X-100 with respect to MEH-PPV was 30%, Triton X-100 molecules penetrated between the polymer chains of the organic light-emitting material, thereby reducing the interactions, and the fibril structure disappeared.

### Experimental Example 3

### Results of Analysis on Ion Transport Properties of Organic Light-Emitting Layer

For each of the organic light-emitting layers manufactured in Preparation Example 1 (TX 30%), Preparation Example 2 (TX 20%), Preparation Example 3 (TX 10%) and Comparative Preparation Example 1 (MEH-PPV), changes in the ionic conductivity of the organic light-emitting layer depending on the weight ratio of Triton 100 with respect to MEH-PPV were measured using an electrochemical impedance spectrometer.

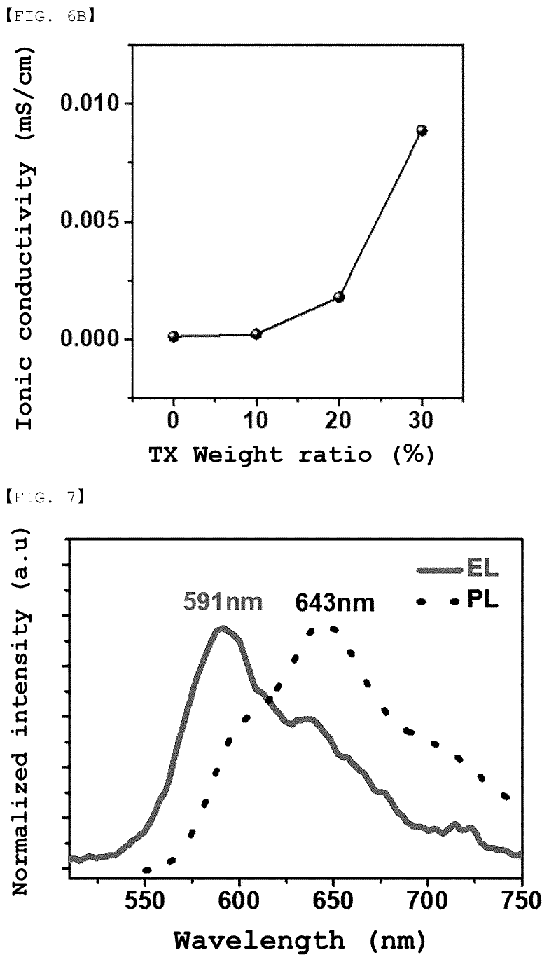

FIG. 6a is a Nyquist plot of the organic light-emitting layer depending on the weight ratio of Triton X-100 with respect to MEH-PPV measured using an electrochemical impedance spectrometer.

FIG. 6b is a graph presenting ionic conductivity depending on the weight ratio of Triton X-100 with respect to MEH-PPV. Specifically, FIGS. 6a and 6b are graphs presenting the measurement results of electrochemical impedance spectroscopy.

Referring to FIGS. 6a and 6b, it was identified that ionic conductivity of the organic light-emitting layer was improved by adding Triton X-100 since the hydrophilic group of Triton X-100 performed a role of improving ion transport, and this could be a method advantageous for developing low-voltage electrochemical devices.

### Experimental Example 4

### Light-Emitting Properties of Organic Light-Emitting Layer

For the organic light-emitting layer manufactured in Preparation Example 1 (TX 30%), photoluminescence and electroluminescence spectra of the organic light-emitting layer in which the weight ratio of Triton X-100 with respect to MEH-PPV was 30% were measured using a spectrometer.

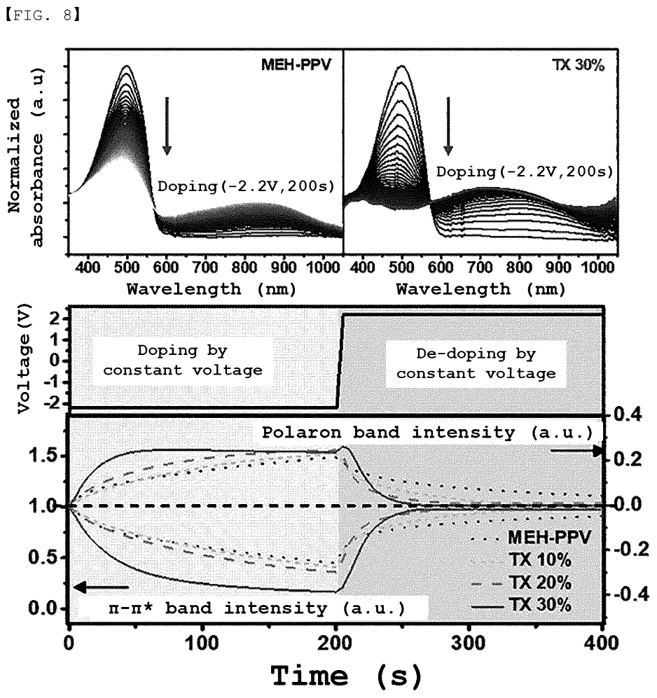

FIG. 7 is a graph presenting spectra of photoluminescence and electroluminescence of the organic light-emitting synaptic device.

For each of the organic light-emitting layers manufactured in Preparation Example 1 (TX 30%), Preparation Example 2 (TX 20%), Preparation Example 3 (TX 10%) and Comparative Preparation Example 1 (MEH-PPV), changes in the voltage-dependent absorbance of the organic light-emitting layer depending on the weight ratio of Triton X-100 with respect to MEH-PPV were measured using a UV-visible Spectrophotometer.

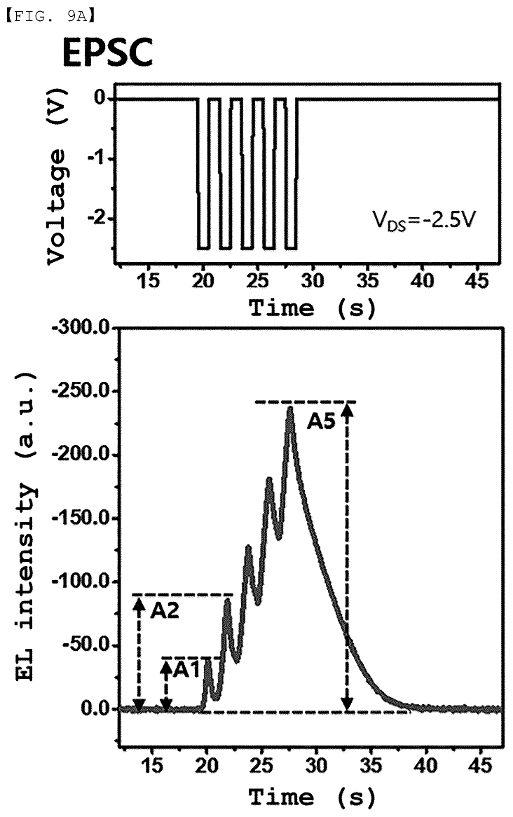

FIG. 8 shows graphs presenting changes in the voltage-dependent absorbance of the organic light-emitting layer depending on the weight ratio of Triton X-100 with respect to MEH-PPV measured using a UV-visible spectrophotometer.

Referring to FIG. 8, as the weight ratio of Triton X-100 with respect to MEH-PPV increased, the rate of changes in the absorbance increased for constant −2.2 V doping and +1.8 V dedoping voltages applied for 200 seconds each. This suggests that the method may be advantageous for developing low-voltage electrochemical devices since Triton X-100 has properties of improving ion transport properties of an organic light-emitting layer without interfering with electrochemical doping.

### Experimental Example 5

### Light-Emitting Synaptic Properties of Organic Light-emitting Synaptic Device

For the organic light-emitting synaptic device manufactured in Example 1-1, light-emitting synaptic properties of the organic light-emitting synaptic device were measured using a semiconductor analyzer (Keithley) (B1500A) and an optical power detector (photodiode) (818-SL/DB optical power detector, silicon, 400 nm to 1100 nm, DB15 calibration module).

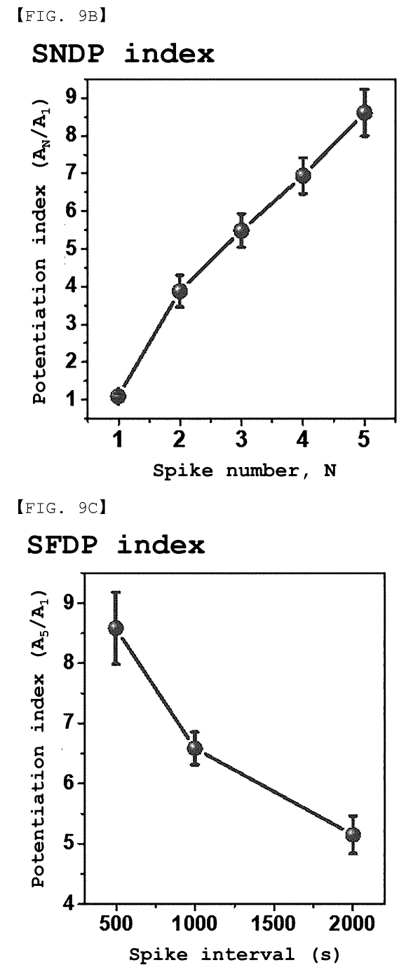

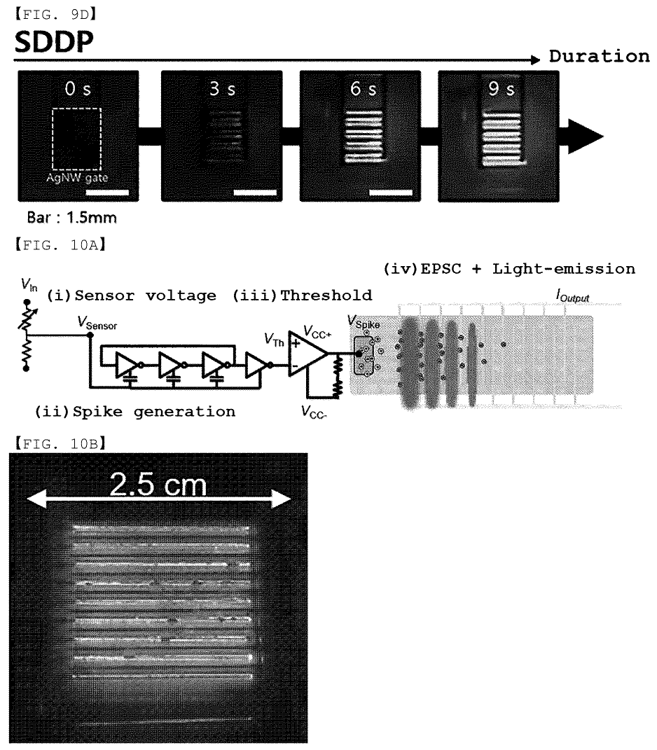

FIG. 9a is a graph presenting excitatory postsynaptic current (EPSC) properties depending on an input spike voltage of the organic light-emitting synaptic device.

FIG. 9b is a graph presenting spike number dependent plasticity of the organic light-emitting synaptic device.

FIG. 9c is a graph presenting spike frequency dependent plasticity of the organic light-emitting synaptic device.

FIG. 9d is a graph presenting spike duration dependent plasticity of the organic light-emitting synaptic device.

Referring to FIGS. 9a to 9d, it was identified that the organic light-emitting synaptic device according to the present disclosure transmits an output signal in the form of luminescence intensity for an input spike, and therefore, is a driving efficient device capable of signal processing and visualization at the same time without an external computer or circuit.

### Experimental Example 6

### Evaluation on Low-Temperature Burn Warning System Using Stimuli-Responsive Neuromorphic Display Device (Thermal Stimuli)

A low-temperature burn warning system using in-display signal processing was implemented using the stimuli-responsive neuromorphic display device manufactured in Example 2. Specifically, a system in which a sensor voltage output is generated only above a certain temperature, and output current and light-emitting area of the organic light-emitting synaptic device are potentiated, showing gradual increases in the response by repeatedly applying a spike through the artificial neuron circuit was implemented.

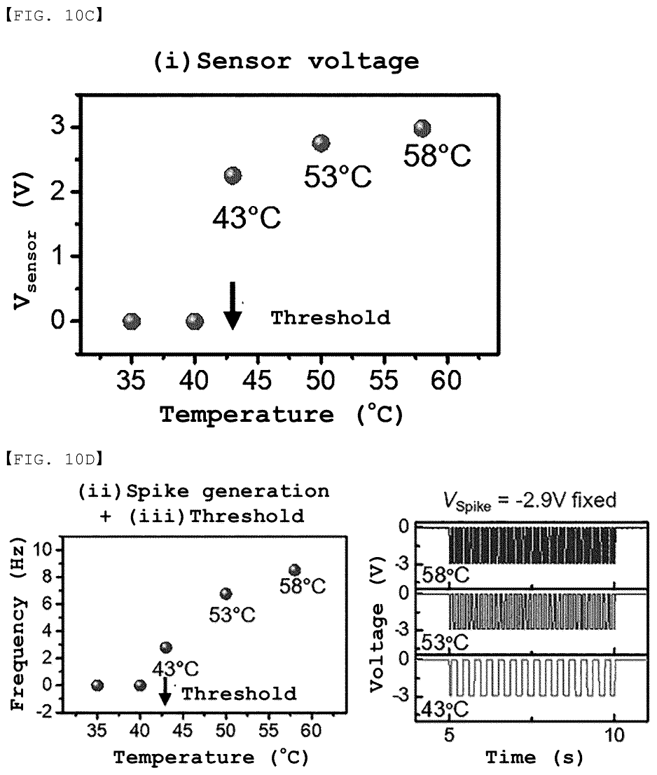

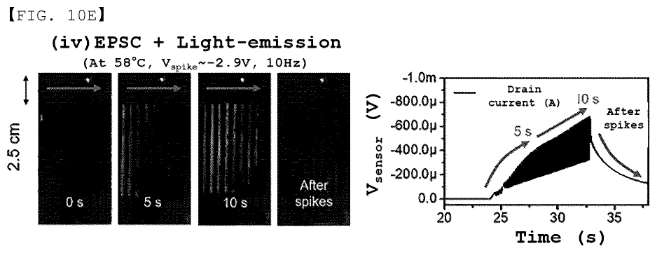

FIG. 10a is a mimetic diagram of the stimuli-responsive neuromorphic display device using in-display signal processing. Referring to FIG. 10a, the voltage (V_{Sensor}) outputted from the artificial sensory receptor circuit is controlled by the ratio between the resistance of the temperature sensor and the resistance value of the load resistor forming the voltage distributor [V_{Sensor}=V_{Input}*(R_{Load}/(R_{Load}+R_{Sensor}))]. The organic light-emitting synaptic device having a side gate structure controls the degree of electrochemical doping of the organic light-emitting layer by a gate voltage, and charges are induced into the organic light-emitting layer to show a response of a drain current imitating postsynaptic action potential. When the synaptic spike voltage is applied to the gate electrode of the organic light-emitting synaptic device, anions of the ionic dielectric layer migrate to the source electrode, and the organic light-emitting material on the source electrode is doped.

FIG. 10b is a photograph of the organic artificial synaptic device emitting light in the stimuli-responsive neuromorphic display device manufactured in Example 2.

FIG. 10c is a graph presenting an output sensor voltage of the voltage divider depending on temperature.

FIG. 10d shows graphs presenting output frequency and spike of the artificial neuron circuit depending on temperature.

FIG. 10e shows photographs presenting changes in the light-emitting area of the stimuli-responsive neuromorphic display device at 58° C. and a graph presenting an output current. Referring to FIG. 10e, holes are temporarily induced from the source electrode to the semiconducting structure to generate an excitatory postsynaptic current (EPSC), and simultaneously with such postsynaptic signal generation, nine light-emitting pixels may be controlled without an external computer or control circuit, and it was identified that the light-emitting area increased as the stimuli accumulated, enabling intuitive and immediate warning signal transmission.

### Experimental Example 7

### Evaluation on Posture Correction Warning System Using Stimuli-Responsive Neuromorphic Display Device (Physical Stimuli)

A posture correction warning system using in-display signal processing was implemented by forming an artificial sensory receptor circuit using a strain sensor instead of the temperature sensor in the stimuli-responsive neuromorphic display device manufactured in Example 2. Specifically, the posture correction warning system was implemented as a system in which a sensor voltage output is generated only above a certain strain, and output current and light-emitting area of the organic light-emitting synaptic device are potentiated, showing gradual increases in the response by repeatedly applying a spike through the artificial neuron circuit.

The voltage (V_{Sensor}) outputted from the artificial sensory receptor circuit is controlled by the ratio between the resistance of the strain sensor and the resistance value of the load resistor forming the voltage distributor [V_{Sensor}=V_{Input}*(R_{Load}/(R_{Load}+R_{Sensor}))]. The organic light-emitting synaptic device having a side gate structure controls the degree of electrochemical doping of the organic light-emitting layer by a gate voltage, and charges are induced into the organic light-emitting layer to show a response of an excitatory postsynaptic current (EPSC) imitating postsynaptic action potential. Such a postsynaptic signal is amplified and then applied to light-emitting pixels, having a threshold at 30% strain, and it was identified that the number of light-emitting pixels that were turned on when stimuli accumulated for 5 seconds was 4 and the number of light-emitting pixels that were turned on when stimuli accumulated for 10 seconds was 10 at 30% strain. Accordingly, it was identified that, by determining a threshold for spinal joint strain and accumulating the stimuli, the light-emitting area increased, and it was possible to transmit an intuitive and immediate warning signal.

### Experimental Example 8

### Evaluation on Nitrogen Dioxide (NO₂) Warning System Using Stimuli-Responsive Neuromorphic Display Device (Chemical Stimuli)

A nitrogen dioxide (NO₂) warning system using in-display signal processing was implemented by forming an artificial sensory receptor circuit using a nitrogen dioxide (NO₂) sensor instead of the temperature sensor in the stimuli-responsive neuromorphic display device manufactured in Example 2. Specifically, the nitrogen dioxide (NO₂) warning system was implemented as a system in which a sensor voltage output is generated under all exposure circumstances with a threshold concentration of 0 ppm, and output current and light-emitting area of the organic light-emitting synaptic device are potentiated, showing gradual increases in the response by repeatedly applying a spike through the artificial neuron circuit.

The voltage (V_{Sensor}) outputted from the artificial sensory receptor circuit is controlled by the ratio between the resistance of the nitrogen dioxide (NO₂) sensor and the resistance value of the load resistor forming the voltage distributor [V_{Sensor}=V_{Input}*(R_{Load}/(R_{Load}+R_{Sensor}))]. The organic light-emitting synaptic device having a side gate structure controls the degree of electrochemical doping of the organic light-emitting layer by a gate voltage, and charges are induced into the organic light-emitting layer to show a response of an excitatory postsynaptic current (EPSC) imitating postsynaptic action potential. It was identified that such a postsynaptic signal is amplified and then applied to light-emitting pixels, and the number of light-emitting pixels that were turned on when 100 ppm of nitrogen dioxide (NO₂) accumulated for 3 seconds was 8, and the number of light-emitting pixels that turned on when 100 ppm of nitrogen dioxide (NO₂) accumulated for 5 seconds was 10. Accordingly, it was identified that, by accumulating stimuli of nitrogen dioxide (NO₂) affecting a living body, the light-emitting area increased, and it was possible to transmit an intuitive and immediate warning signal.

### Experimental Example 9

### Evaluation on Ultraviolet (365 nm) Exposure Warning System Using Stimuli-Responsive Neuromorphic Display Device (Electromagnetic Stimuli)

An ultraviolet (365 nm) exposure warning system using in-display signal processing was implemented by forming an artificial sensory receptor circuit using an optical sensor (photodiode) instead of the temperature sensor in the stimuli-responsive neuromorphic display device manufactured in Example 2. Specifically, the ultraviolet (365 nm) exposure warning system was implemented as a system in which a threshold exposure time is 3 seconds, and a sensor voltage output is generated when the time is longer than 3 seconds, and output current and light-emitting area of the organic light-emitting synaptic device are potentiated, showing gradual increases in the response by repeatedly applying a spike through the artificial neuron circuit.

The voltage (V_{Sensor}) outputted from the artificial sensory receptor circuit is controlled by the ratio between the resistance of the optical sensor (photodiode) and the resistance value of the load resistor forming the voltage distributor [V_{Sensor}=V_{Input}*(R_{Load}/(R_{Load}+R_{Sensor}))]. The ultraviolet light source has a peak at 365 nm, and a spectrum range of 350 nm to 400 nm. The organic light-emitting synaptic device having a side gate structure controls the degree of electrochemical doping of the organic light-emitting layer by a gate voltage, and charges are induced into the organic light-emitting layer to show a response of an excitatory postsynaptic current (EPSC) imitating postsynaptic action potential. It was identified that such a postsynaptic signal is amplified and then applied to light-emitting pixels, and the number of light-emitting pixels that were turned on when ultraviolet (365 nm) accumulated for 5 seconds was 2, and the number of light-emitting pixels that were turned on when ultraviolet (365 nm) accumulated for 10 seconds was 10. Accordingly, it was identified that, by accumulating stimuli caused by exposure to ultraviolet, the light-emitting area increased, and it was possible to transmit an intuitive and immediate warning signal.

Hereinbefore, the present disclosure has been described with limited examples, however, the present disclosure is not limited thereto, and it is obvious that various changes and modifications may be made by those skilled in the art within technical ideas of the present disclosure and the range of equivalents of the claims to be described.

### REFERENCE NUMERAL

10: Artificial sensory receptor circuit
20: Artificial neuron circuit
30: Organic light-emitting synaptic device
11: Load resistor
12: Sensor
21: Ring oscillator
22: Comparator

1. An organic light-emitting synaptic device comprising:
an organic light-emitting layer including an organic light-emitting material and a plasticizer;
an ionic dielectric layer; and
two or more terminals,
wherein the plasticizer includes a surfactant having both hydrophilicity and hydrophobicity, and
the organic light-emitting synaptic device provides luminescence output and current output at the same time under an electrochemical doping-based driving principle.

2. The organic light-emitting synaptic device of claim 1, which has at least one structure selected from the group consisting of a transistor, a diode, a resistor, a capacitor, an inductor, an ion pump, an ion cell (battery), a flash memory, a magnetic random access memory, a memristor, a resistive random access memory, a magnetoresistive random access memory and a phase-change memory.

3. The organic light-emitting synaptic device of claim 1, wherein the organic light-emitting material is an organic molecule light-emitting material having a conjugation structure, an organic polymer light-emitting material having a conjugation structure, an organic/inorganic perovskite light-emitting material, or a mixture thereof.

4. The organic light-emitting synaptic device of claim 3, wherein the organic small-molecule light-emitting material includes one selected from the group consisting of pentacene, TIPS-pentacene (6,13-bis(triisopropylsilylethynyl) pentacene), rubrene, tetracene, anthracene, triethylsilylethynyl anthradithiophene (TES ADT), (6,6)-phenyl-C61 butyric acid methyl ester (PCBM), fluorene, pyrene, tris(2-phenylpyridine)iridium (III) (Ir(ppy)₃), (2-phenylpyridine) (acetylacetonate iridium (III) (Ir(ppy)₂(acac)), 4,4′-bis(N-carbazolyl)-1,1′-biphenyl (CBP), spiro-OMeTAD (2,2′,7,7′-tetrakis (N,N-di-p-methoxyphenylamine) 9,9′-spirobifluorene), 2,2′-bipyridine (bpy), 1,10-phenanthroline (phen), perylene, poly(p-phenylene vinylene) (PPV) and combinations thereof.

5. The organic light-emitting synaptic device of claim 3, wherein the organic polymer light-emitting material includes one selected from the group consisting of polythiophene, poly(3-hexylthiophene) (P3HT), poly(3-octylthiophene) (P30T), poly(butylthiophene) (PBT), poly(3,4-ethylenedioxythiophene) (PEDOT), poly(9-vinylcarbazole) (PVK), poly(p-phenylene vinylene), poly(thienylene vinylene) (PTV), polyacetylene, polyfluorene, polyaniline, polypyrrole, diketopyrrolopyrrole-based copolymers, isoindigo-based copolymers, derivatives thereof and combinations thereof.

6. The organic light-emitting synaptic device of claim 3, wherein organic/inorganic perovskite light-emitting material includes one selected from the group consisting of formamidinium lead trihalide (FAPbX₃, X═Cl, Br, I), methylammonium lead trihalide (MAPbX₃, X═Cl, Br, I), phenethylammonium lead trihalide (PEAPbI₃, X═Cl, Br, I), guanidinium lead thiocyanate (GAPb(SCN)₃), cesium lead bromide (CsPbBr₃), cesium lead iodide (CsPbI₃), cesium lead chloride/bromide (CsPb(Cl/Br)₃), cesium lead chloride/ iodide (CsPb(Cl/I)₃) and combinations thereof.

7. The organic light-emitting synaptic device of claim 1, wherein the surfactant is a nonionic surfactant, an ionic surfactant or a mixture thereof.

8. The organic light-emitting synaptic device of claim 7, wherein the nonionic surfactant includes one selected from the group consisting of polysorbate, polyethylene glycol (PEG), nonoxynol-9, octoxynol-9 (Triton X-100), alkyl polyglucoside (APG), ethylene oxide/propylene oxide copolymers, derivatives thereof and combinations thereof.

9. The organic light-emitting synaptic device of claim 7, wherein the ionic surfactant includes one selected from the group consisting of sodium dodecyl sulfate (SDS), sodium lauryl sulfate (SLS), cetyltrimethylammonium bromide (CTAB), benzalkonium chloride (BAC), cocamidopropyl betaine (CAPB), sodium cocoyl isethionate (SCI), dioctyl sulfosuccinate (DOSS), sodium oleate, sodium stearate, sodium cholate, derivatives thereof and combinations thereof.

10. The organic light-emitting synaptic device of claim 1, wherein the ionic dielectric layer includes an ionic dopant characterized in that cations and anions are separated by an applied electric signal.

11. The organic light-emitting synaptic device of claim 10, wherein the ionic dopant includes cations of imidazolium, ammonium, pyrrolidinium, sulphonium, phosphonium, pyridinium and derivatives thereof; anions of chloride, iodide, bromide, sulfate, sulfonate, phosphate, phosphinate, aluminate, acetate, thiocyanate, dicyanamide, borate, antimonite, bis(sulfonyl) imide-based, tosylate, nitrate, decanoate, thiosalicylate, benzoate and derivatives thereof; or mixtures thereof.

12. The organic light-emitting synaptic device of claim 1, which has a transistor structure including three or more terminals.

13. The organic light-emitting synaptic device of claim 12, comprising:
a gate electrode;
the organic light-emitting layer forming a channel region;
the ionic dielectric layer including an ionic dopant formed between the gate electrode and the channel region;
a source electrode connected to the channel region; and
a drain electrode connected to the channel region.

14. The organic light-emitting synaptic device of claim 13, wherein the gate electrode controls electrochemical doping from the ionic dielectric layer to the channel region.

15. A stimuli-responsive neuromorphic display device comprising:
at least one artificial sensory receptor circuit that senses stimuli;
at least one artificial neuron circuit that receives a voltage signal from the artificial sensory receptor circuit, determines a threshold of the stimuli, and outputs a spike signal when breaking through the threshold; and
the organic light-emitting synaptic device of any one of claims 1 to 14 accumulating the spike signal and visualizing it through luminescence.

16. The stimuli-responsive neuromorphic display device of claim 15, wherein the artificial sensory receptor circuit includes at least one load resistor and at least one voltage source.

17. The stimuli-responsive neuromorphic display device of claim 15, wherein the artificial sensory receptor circuit includes at least one sensor selected from the group consisting of a temperature sensor, a strain sensor or a pressure sensor, an optical sensor, an image sensor that senses visual information, an acceleration sensor that senses a balance, a gyroscope sensor and a gas sensor that senses chemical substances inside or outside a living body.

18. The stimuli-responsive neuromorphic display device of claim 17, wherein the temperature sensor includes at least one temperature-sensitive resistive material selected from the group consisting of polymers; carbon nanotubes; carbon nanofibers; carbon black; graphene; graphene oxide; transition metal dichalcogenides; MXene; inorganic semiconductor membranes; metals having a nanostructure of one of nanoparticles, nanorods, nanowires and nanoflakes; and semiconducting nanowires.

19. The stimuli-responsive neuromorphic display device of claim 17, wherein the temperature sensor is at least one selected from the group consisting of a piezoresistive strain sensor, a piezoelectric strain sensor, a triboelectric strain sensor and a capacitive strain sensor, which change an electric signal by changing resistance, current, voltage and permittivity according to thermal stimuli or changing optical properties by changing light transmittance and light absorptivity.

20. The stimuli-responsive neuromorphic display device of claim 15, wherein the artificial neuron circuit includes a ring oscillator that changes the voltage signal into a spike form, and a comparator that determines whether the voltage signal breaks through a threshold.

21. The stimuli-responsive neuromorphic display device of claim 15, wherein the threshold is intensity of stimuli to which a sensory receptor or a pain receptor of a living body responds.

22. The stimuli-responsive neuromorphic display device of claim 15, wherein the stimuli are thermal stimuli, and the stimuli-responsive neuromorphic display device performs at least one of a low-temperature burn prevention warning function of determining a thermal pain threshold of human skin, and accumulating and visualizing the thermal stimuli; and an overheat warning function of sensing a temperature of an electronic device, and accumulating and visualizing the thermal stimuli.

23. The stimuli-responsive neuromorphic display device of claim 15, wherein the stimuli are physical stimuli, and the stimuli-responsive neuromorphic display device performs at least one of a function of determining a threshold of pressure causing bedsores and the like on human skin, and accumulating and visualizing the pressure stimuli; a function of measuring noise at an industrial site and visualizing the noise concentration; an arrhythmia warning function of determining and visualizing a heart rate threshold dangerous to a living body; a function of determining a threshold of the degree of bending that strains a joint, and accumulating and visualizing the bending stimuli; a function of determining a threshold of crack formation on a building or a structure such as a bridge caused by physical stimuli such an earthquake, and accumulating and visualizing the physical stimuli; and a function of measuring an impact applied to a safety helmet, and accumulating and visualizing the impact.

24. The stimuli-responsive neuromorphic display device of claim 15, wherein the stimuli are chemical stimuli, and the stimuli-responsive neuromorphic display device performs at least one of a function of determining a gas concentration threshold affecting human tissue during breathing, and visualizing the gas concentration; a function of measuring and visualizing a carbon oxide concentration inside a building; a fine dust warning function of measuring and visualizing a fine dust concentration in the air; a function of measuring air quality and visualizing changes in the air quality; and a disease risk warning function of determining and visualizing a threshold of a concentration of a specific molecule indicating a disease in a living body.

25. The stimuli-responsive neuromorphic display device of claim 15, wherein the stimuli are electromagnetic stimuli, and the stimuli-responsive neuromorphic display device performs at least one of a function of determining a threshold of ultraviolet (wavelength 100 nm to 400 nm) stimuli affecting human tissue, and accumulating and visualizing the ultraviolet stimuli; a function of determining a threshold of X-ray (wavelength 0.01 nm to 10 nm) stimuli affecting human tissue, and accumulating and visualizing the X-ray stimuli; and a function of determining a threshold of radiation exposure (gamma ray wavelength 0.01 nm or less), and visualizing the risk of radiation exposure.
